(19) United States
(12) Patent Application Publication
(10) Pub. No.: US 2024/0428842 A1
(43) Pub. Date: Dec. 26, 2024

(54) APPARATUSES AND METHODS FOR MULTIPLE TYPES OF ALERT ALONG ALERT BUS

(71) Applicant: Micron Technology, Inc., Boise, ID (US)

(72) Inventors: Yang Lu, Boise, ID (US); Randall J. Rooney, Boise, ID (US); David R. Brown, Boise, ID (US); Michael A. Shore, Boise, ID (US); Kang-Yong Kim, Boise, ID (US)

(73) Assignee: Micron Technology, Inc., Boise, ID (US)

(21) Appl. No.: 18/743,309

(22) Filed: Jun. 14, 2024

Related U.S. Application Data
(60) Provisional application No. 63/510,305, filed on Jun. 26, 2023.

(51) Int. Cl. G11C 11/406; G11C 11/4076

(52) U.S. Cl. CPC G11C 11/40622; G11C 11/40615; G11C 11/4076

(57) ABSTRACT

Apparatuses, systems, and methods for multiple types of alert along an alert bus. A memory device may detect multiple types of alert and use an alert signal along an alert bus to signal a controller of these alerts. Different pulse widths of the alert signal may be used to indicate the type of alert. For example if the alert signal is at an active level between a first duration and a second duration, it may indicate a first type of alert, if the alert signal is active between a third duration and a fourth duration, it may indicate a second type of alert. If the alert signal remains active for longer than a threshold amount of time, it may indicate a third type of alert.

### CROSS REFERENCE TO RELATED APPLICATION(S)

This application claims the benefit under 35 U.S.C. § 119 of the earlier filing date of U.S. Provisional Application Ser. No. 63/510,305 filed Jun. 26, 2023 the entire contents of which are hereby incorporated by reference in its entirety for any purpose.

### BACKGROUND

Information may be stored on memory cells of a memory device. The memory cells may be organized at the intersection of word lines (rows) and bit lines (columns). Information in the memory cells may decay over time. For example, the information may be stored as a charge on a capacitor which may decay over time. The memory device may perform refresh operations to restore the information and prevent information from being lost.

There may be situations in which the memory detects an error or other issue. The memory may signal a controller or host device which is operating the memory, for example by providing an alert signal along an alert pin. Responsive to the alert signal, the controller may take note the error and/or take one or more actions to mitigate, correct, and/or otherwise resolve the error.

### BRIEF DESCRIPTION OF THE DRAWINGS

FIG. 1 is a block diagram of a semiconductor device according to an embodiment of the present disclosure.

FIG. 2 is a set of timing diagrams which represent different types of alerts which can be provided along an alert bus.

FIG. 3 is a block diagram of a memory system according to some embodiments of the present disclosure.

FIG. 4 is a timing chart of types of alert according to some embodiments of the present disclosure.

FIG. 5 is a flow chart of a method of providing multiple types of alert along an alert bus according to some embodiments of the present disclosure.

FIG. 6 is a flow chart of a method of determining a type of alert along an alert bus with a controller according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a memory array may be accessed by one or more access operations, such as read or write operations. During an example access operation a word line may be activated based on a row address and then selected memory cells along that active word line may have their information read or written to based on which bit lines are accessed, which may be based on a column address.

The memory may include various circuits which monitor and/or attempt to protect the integrity of the data in the array. For example, the memory may include an error correction code circuit, which checks information read from the memory array to determine if there is an error in the information (e.g., a changed bit) and correct the error if possible. A memory may include a refresh control circuit, which performs various refresh operations to ensure that the information in the array does not decay over time to the point where information is lost.

If the memory device detects an error, fault, or other type of issue, a signal may be provided to the controller indicating that an error was detected. The memory may use an alert bus, which is coupled from an alert pin of the memory to the controller. To save on space, since alerts may generally be relatively rare, the alert bus may be a single conductive element, and the alert signal may be a binary signal (e.g., either active or inactive). However, as memory devices become more complex, there may be a need to increase the number of types of alert which can be communicated to the controller along the alert bus. There may thus be a need to signal multiple alert types using the alert signal along the alert bus.

The present disclosure is drawn to apparatuses, systems, and methods for multiple types of alert along an alert bus. A memory device uses pulse width of an alert signal along the alert bus to indicate multiple types of alert. The memory may determine that an alert signal should be sent and then an alert generator circuit of the memory may drive the alert pin (and the alert bus) to an active level. How long the alert signal is kept at the active level depends on the type of alert. For example, the memory may keep the alert signal active for a first number of clock cycles for a first type of alert or for a second number of clock cycles for a second type of alert. Some types of alert may remain active until the controller performs an action. The controller has an alert logic circuit which is coupled to the alert bus. When the alert signal becomes active (e.g., the alert bus is detected to be at the active level) the alert logic circuit may begin counting clock cycles. Based on when (and if) the alert signal returns to an inactive level, the type of alert may be determined. For example, if the count is between a first value and a second value it may be the first type of alert. If the count is between a third value and a fourth value, it may be the second type of alert. If the alert signal is still active after a threshold amount of time (e.g., after a fifth value of clock cycles are counted) then it may be determined to be a third type of alert.

Terms such as fault, error and alert may be used herein to refer to any detected condition and/or event within the memory which the memory desires to communicate to the controller along the alert bus. The types of alert do not necessarily include issues which cause problems, or which require intervention from the controller. Some types of alert may simply be informative. Some types of alert may indicate that data integrity is at risk or has already been compromised. Some types of errors may require correction or other action by the controller. The controller may determine what action to take, if any, based on the determined type of alert. The different types of alert which are communicated, as well as what actions the controller takes, may be based on the specific implementation of the memory and/or controller. While an example implementation with example types of alerts is discussed herein, the present disclosure is not limited to these specific types of alerts.

In an example implementation, the first type of alert may indicate that an error was detected by the error correction circuits. The second type of alert may indicate that there was an error with the refresh operations of the memory, but not one that requires intervention. The third type of alert may indicate that there was an error with the refresh operations which require an intervention. Responsive to the third type of alert, the controller may provide a refresh management command to the memory. Responsive to receiving the refresh management command, the memory device may return the alert signal to an inactive level.

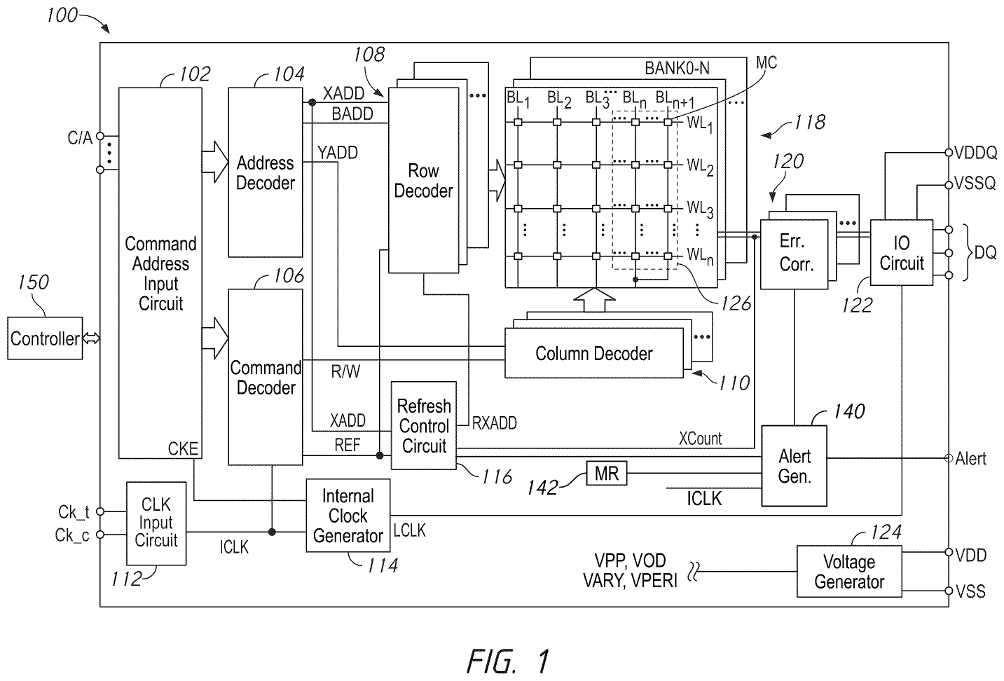

FIG. 1 is a block diagram of a semiconductor device according to at least one embodiment of the disclosure. The semiconductor device 100 may be a semiconductor memory device, such as a DRAM device integrated on a single semiconductor chip. The memory device may be operated by a host or controller 150. The controller 150 may provide various signals to operate the memory, for example by writing data to the memory device 100 and reading data from the memory device 100.

The semiconductor device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. Each memory bank includes a plurality of word lines WL (rows), a plurality of bit lines BL (columns), and a plurality of memory cells MC arranged at intersections of the plurality of word lines WL and the plurality of bit lines BL.

The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank. The bit lines BL are coupled to a respective sense amplifier (SAMP). Read data from the bit line BL is amplified by the sense amplifier SAMP, and transferred to read/write amplifiers 120 over complementary local data lines (LIOT/B), transfer gate (TG), and complementary main data lines (MIOT/B). Conversely, write data outputted from the read/write amplifiers 120 is transferred to the sense amplifier SAMP over the complementary main data lines MIOT/B, the transfer gate TG, and the complementary local data lines LIOT/B, and written in the memory cell MC coupled to the bit line BL.

The semiconductor device 100 may employ a plurality of external terminals (e.g., pins) that include command and address (C/A) terminals coupled to a command and address bus to receive commands and addresses, and a CS signal, clock terminals to receive clocks CK and /CK, data terminals DQ to provide data, and power supply terminals to receive power supply potentials VDD, VSS, VDDQ, and VSSQ. The device 100 also includes an Alert terminal. Each of the external terminals may generally be coupled to a respective bus, which couples the terminal to the controller 150. For example, the data terminals DQ may be coupled along a data bus to the controller 150, the alert terminal Alert may be coupled along an alert bus to the controller 150, etc. In some embodiments, multiple memory devices may be coupled together (e.g., in a memory module) and the bus may be shared by multiple devices. For example, each memory in a module may be coupled in common to a same alert bus.

The clock terminals are supplied with external clocks CK and /CK that are provided to an input circuit 112 by the controller 150. The external clocks may be complementary. The input circuit 112 generates an internal clock ICLK based on the CK and /CK clocks. The ICLK clock is provided to the command decoder 110 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses by the controller 150. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands by the controller 150. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The memory 100 may use the Alert terminal or alert pin (and alert bus) to provide an alert signal to the controller 150. The alert signal may generally be used to indicate that a fault has occurred with the memory 100, although other reasons for using the alert signal may also be used. In some embodiments the alert signal may be a binary signal and the alert bus may be a single conductive element. Accordingly, the alert signal may either be at an active level or an inactive level. For example, a voltage which represents a low logical level may represent an active alert signal and a voltage which represents a high logical level may represent an inactive alert signal or vice versa. The memory 100 may have multiple types of alerts which can be communicated along the alert terminal/alert bus to the controller. An alert generator circuit 140 may receive a signal which indicates a type of alert, and then activate the alert signal (e.g., by driving the alert terminal and alert bus to a voltage which represents an active level). The alert generator circuit 140 may use pulse width to indicate the type of alert and may thus hold the alert signal at the active level for an amount of time based on the type of alert which is being communicated.

In some embodiments, the memory 100 may include a mode register 142. The mode register may include various information and/or settings for the operation of the memory, stored in different registers. Responsive to a fault being detected, an error code and/or information about the fault may be written to a register of the mode register 142. Responsive to receiving the alert signal, the controller 150 may perform a mode register read operation to retrieve information about the cause of the alert signal. In some embodiments, the controller 150 may determine which register to perform a read operation on based on the type of alert signal (e.g., based on a time that the alert signal was active for).

The present disclosure is generally described where error correction and refresh operations are used as examples of types of faults which may lead to different types of alert signals. Accordingly, the memory device 100 is described with respect to an embodiment which includes an error correction circuit 120 and a refresh control circuit 116 which performs certain types of refresh tracking. However, the present disclosure is not limited to these types of faults or alert signals, and other sources of alerts may be used in other example embodiments. In some embodiments, other forms of error correction and/or refreshing may be used, or no error correction and/or refreshing may be used.

In an example write operation the controller 150 provides a write command along with bank, column, and row addresses and data to be written. The write data is supplied to the data terminals DQ and is written to memory cells in the memory array 118 corresponding to the row, column, and bank addresses. The write command is received by the command decoder 106, which provides internal commands so that the write data is received by data receivers in the input/output circuit 122. Write clocks may also be provided to the external clock terminals for timing the receipt of the write data by the data receivers of the input/output circuit 122. The write data is supplied via the input/output circuit 122 to the error correction circuit 120, which generates parity bits based on the write data. The data and parity is written to the memory array 118 at locations specified by the addresses.

In an example read operation, the controller 150 may provide a read command as well as a bank, column, and row address. Responsive to the read command and addresses, the memory 100 reads data from memory cells in the memory array 118 corresponding to the row address XADD and column address YADD. The read command is received by the command decoder 106, which provides internal commands so that read data and parity from the memory array 118 is provided to the error correction circuit 120. The error correction circuit 120 detects and/or corrects errors in the data based on the parity. The corrected read data is output to outside from the data terminals DQ via the input/output circuit 122.

Since the information in the array 118 may decay over time, the memory 100 performs refresh operations to maintain data integrity. The refresh operations may be responsive to commands received from the controller 150 (e.g., auto-refresh or refresh management), may be responsive to commands generated within the memory (e.g., self-refresh) or combinations thereof. A refresh signal REF, which may be generated with internal timing or based on commands from the controller may be used to control the timing of refresh operations. Responsive to the refresh signal REF, the refresh control circuit 116 performs one or more refresh operations by issuing internal refresh commands and a refresh address RXADD. Responsive to the internal refresh commands and the address RXADD, the row decoder 108 may refresh the memory cells along a word line associated with RXADD.

The refresh control circuit 116 may perform a sequential refresh operation or a targeted refresh operation. During a sequential refresh operation, the refresh address RXADD is generated based on refreshing the word lines of the array in a sequence. For example, a counter circuit may increment a previous refresh address to generate a next refresh address. The sequential refresh operations may generally cycle through all of the addresses in the array 118 at a rate such that no information decay is expected.

Certain access patterns may increase a rate of decay such that refreshes need to performed faster than the rate of sequential refreshes. For example, repeated accesses to a row, or row hammer, may increase a rate of decay along memory cells which are nearby (e.g., adjacent to) the hammered row. The accessed row may be referred to as an aggressor row, and the rows with increased decay rate may be referred to as victim rows. The refresh control circuit 116 includes logic which identifies aggressor rows and generates refresh addresses based on the victim rows as part of targeted refresh operations. The refresh control circuit 116 includes a queue of identified aggressors, and when a targeted refresh operation is called for (e.g., either by internal logic or due to a refresh management command from the controller 150), refresh addresses for the victims are calculated and provided as RXADD.

In an example embodiment, the memory device 100 may use per row hammer tracking (PRHT) where each row has an associated access count value XCount. Memory cells along each row, referred to as counter memory cells 126, may be set aside to store the count value XCount for that row. When that row is accessed (e.g., as part of a read or write operation), the value XCount is read out to the refresh control circuit, where it is compared to a threshold, changed based on that comparison, and then written back to the counter memory cells 126. For example, if the count is below the threshold, then the count value XCount may be incremented and then written back. If the count is at or above the threshold, the count value may be reset to an initial value (e.g., 0) and the row address XADD may be stored in the aggressor queue as an identified aggressor address. When a targeted refresh is performed, the address may be removed from the aggressor queue.

In embodiments where error correction is used, the count value XCount may be read out along with one or more pieces of redundant information. The refresh address control circuit 116 may include a count error correction circuit. Based on the redundant information, the count value XCount may be corrected when it is read out to the refresh address control circuit 116. For example, the refresh control circuit 116 may locate and correct errors in all or part of the count value XCount before updating the count value and determining if the updated count value has crossed the threshold. The updated count value along with updated redundant information may be written back to the counter memory cells 126. In some embodiments, the count values in the counter memory cells 126 may also be protected by error correction, for example by strong redundant information in the counter memory cells (e.g., redundant copies of all or a portion of the bits of the count value XCount) and/or by associating one or more count values together with a set of parity bits and using the error correction circuit 120.

In a first example alert type, the error correction circuit 120 may indicate that an error has been detected in data read from the array 118. The error correction circuit 120 may provide a first type of alert signal to the alert generator circuit 140. In some embodiments, the first type of alert signal may be provided responsive to any error being detected. In some embodiments, the first type of alert signal may be provided responsive to the error correction circuit 120 detecting a fault in error correction operations, for example an error which cannot be corrected.

In a second example alert type, the refresh control circuit 116 may provide a second type of alert signal responsive to a fault with error correction of one of the count values XCount. For example, similar to the first type of alert, the second type of alert may be triggered by a repaired error and/or by an error which cannot be repaired in the count values.

In a third example alert type, the refresh control circuit 116 may provide a third type of alert signal responsive to the aggressor queue becoming full. Responsive to being notified of the third type of alert, the controller 150 may issue a refresh management (RFM) command, and responsive to the RFM command, the memory 100 performs targeted refresh operations.

The power supply terminals are supplied with power supply potentials VDD and VSS. The power supply potentials VDD and VSS are supplied to an internal voltage generator circuit 124. The internal voltage generator circuit 124 generates various internal potentials VPP, VARY, VPERI, and the like based on the power supply potentials VDD and VSS supplied to the power supply terminals. The internal potential VPP is mainly used in the row decoder 108, the internal potentials VARY are mainly used in the sense amplifiers SAMP included in the memory array 118, and the internal potential VPERI is used in many peripheral circuit blocks.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

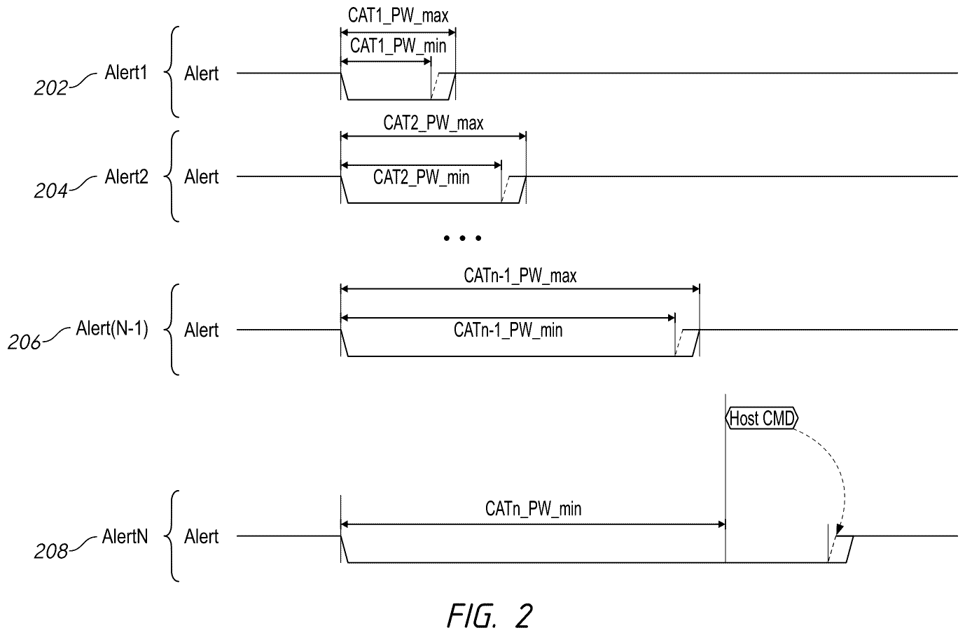

FIG. 2 is a set of timing diagrams which represent different types of alerts which can be provided along an alert bus. The timing diagrams 202-208 show different types of alert signals along an alert bus. For example, the types of alert represented by graphs 202-208 may represent an alert signal provided by an alert generator circuit of a memory (e.g., 140 of FIG. 1) responsive to a determination that a fault was detected in the memory. The graphs 202-208 represent a set of N different types of alert which may be signaled along the alert bus. The N different types of alert may correspond to N different types of fault which the memory can signal along the alert bus.

Each of the graphs 202-208 shows a voltage along an alert bus (and an alert pin of the memory). In the example of FIG. 2, the Alert signal along the alert bus may be inactive at a first voltage and active a second voltage which is less than the first voltage. For the sake of comparison, each of the graphs 202-208 is aligned so that the alert generator circuit drives the alert signal to an active level at a same time. The different types of alert each have a different pulse width (e.g., a different length of time where the alert signal is at the active level). The durations may be measured in cycles of a clock signal such as CK and/or/CK of FIG. 1. The graphs are aligned to allow for easier comparison of the pulse lengths. Since in example embodiments the alert bus may be a single conductive element (e.g., a one bit signal) the different alerts would happen at separate times, rather than aligned as shown.

The graph 202 shows a first type of alert Alert1, where the alert signal is at the active level for a duration which is between a maximum and minimum category 1 pulse width, CAT1_PW_max and CAT1_PW_min. The graph 204 shows a second type of alert Alert2, where the alert signal is at the active level for a duration which is between CAT2_PW_max and CAT2_PW_min. The graph 206 shows an (N−1)th type of alert where the alert signal is at the active level for a duration which is between CATn−1_PW_max and CATn−1_PW_min. The graph 208 shows an Nth type of alert where the alert signal is at the active level for at least a duration CATn_PW_min.

Ranges of possible duration may be used to help prevent ambiguous signaling if the timing of the alert signal is not exactly in sync with the clock signal. Each type of alert has a maximum duration which is shorter than the minimum duration of the alert type with the next longest pulse width to prevent overlap and further reduce ambiguity. For example, the duration CAT2_PW_min is longer than the duration CAT1_PW_max and the duration CATn_PW_min is longer than the duration CATn−1_PW_max. In some embodiments, a buffer amount of time may be added between the ranges of different alert types to further reduce ambiguity. For example, CAT2_PW_min may be set to CAT1_PW_max+a buffer time.

In some embodiments, the memory may provide the alert signal with set timing (e.g., based on settings of the memory) while the controller may use a range of possible times to differentiate between types of alert. For example, responsive to a second type of alert, the memory may provide the alert signal for a time CAT2_PW which is between CAT2_PW_max and CAT_PW_min. The controller may detect that the duration of time that the alert signal was active was above CAT2_PW_min but below CAT2_PW_max and thus identify the type of alert as Alert2.

The alert type with the longest pulse width (in this example AlertN of graph 208) may be open ended. In other words, the alert signal may be active for a duration which is at least CATn_PW_min, but there may not be a specified maximum amount of time the alert signal is active for that type of alert. Instead, the alert signal may remain at the active level until a command is received from the controller (or host). Responsive to the command from the controller, the alert signal may be returned to the inactive level. For example, if the controller determines that the time the alert signal has been active is at or greater than CATn_PW_min, it may identify the alert as AlertN, and respond accordingly by providing a command.

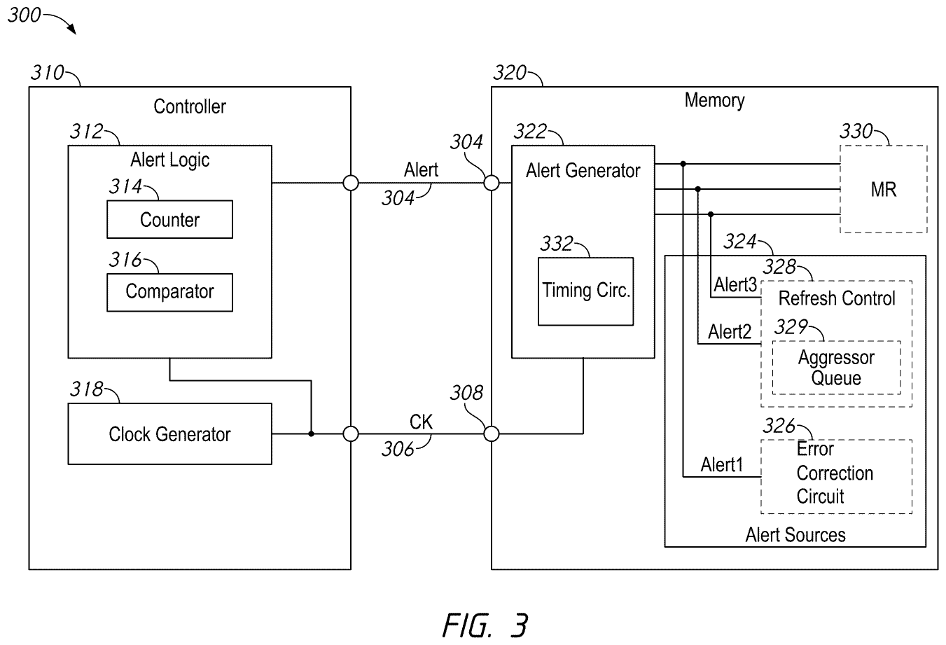

FIG. 3 is a block diagram of a memory system according to some embodiments of the present disclosure. The memory system 300 represents certain components of a controller 310 and memory 320 which may be used to send and receive alert signals along an alert bus 302. In some embodiments, the controller 310 may represent the controller 150 of FIG. 1 and the memory 320 may represent the memory device 100 of FIG. 1. For the sake of clarity, certain signals and components have been omitted from the view of FIG. 3. For example, components such as the memory array, row and column decoders, clock input circuit which were previously described with respect to the example memory device 100 of FIG. 1 are not discussed again with respect to FIG. 3.

The controller 310 includes a clock generator circuit 314 which provides a clock signal CK (e.g., CK and /CK of FIG. 1) along a clock bus 306 to a clock terminal 308 of the memory 320. The memory 320 includes various alert sources which may issue internal alert detection signals, each of which is associated with a different type of alert. In this example three alert detection signals are shown, Alert1, Alert2, and Alert3. An alert generator circuit 322 of the memory 320 activates an alert signal by driving a voltage of an alert terminal 304 and alert bus 302 responsive to one of the alert detection signals. The alert generator circuit 322 maintains the alert signal at an active level for an amount of time, measured in cycles of the clock signal CK (and/or an internal clock signal derived therefrom, such as ICLK of FIG. 1), where the amount of time is based on the alert detection signal (e.g., the type of alert). The controller 312 includes alert logic which monitors the voltage along the alert bus 302 and begins count clock cycles of CK when the alert signal becomes active. Based on the count, the alert logic 312 determines a type of the alert.

The clock generator circuit 318 of the controller 310 provides a periodic clock signal CK. The clock signal CK may represent a system clock signal directly provided by the clock generator 318 and/or one or more signals derived therefrom. The derivative clock signals may have a fixed relationship with the system clock (e.g., half the frequency, twice the frequency, with a phase delay, etc.). For example, the memory 320 may generate one or more internal clock signals based on the clock signal CK received through the clock terminal 308. For the sake of clarity only a single clock signal CK is discussed with respect to FIG. 3.

The controller 310 includes an alert logic circuit 312 which is coupled to the alert bus 302 (e.g., via an alert terminal of the controller 310). In some embodiments, the alert bus 302 may be coupled to multiple memory devices. In some embodiments, the alert bus 302 may be coupled to a single memory device such as 320. The alert logic circuit 312 monitors a voltage along the alert bus 302 to determine a level of an alert signal. When the voltage changes (e.g., when the alert signal changes from an inactive to an active level), a counter circuit 314 of the alert logic circuit 312 begins counting in sync with the clock signal CK. For example, on each rising edge of the clock signal CK, the counter circuit 314 may increment a count value.

The alert logic circuit 312 also includes a comparator circuit 316 which compares the count value to a variety of thresholds or values. When the alert signal falls to an inactive level (or if the count value crosses a final threshold), the comparator circuit checks the count value against the thresholds to determine the type of alert signal. For example, if the count is between a first threshold and a second threshold (e.g., CAT1_PW_min and CAT1_PW_max of FIG. 2) then a first type of alert may be determined. If the count is between a third threshold and a fourth threshold (e.g., CAT2_PW_min and CAT2_PW_max of FIG. 2) then a second type of alert may be determined. The comparator circuit 316 may also compare the count to a final threshold even while the count value is still changing (e.g., while the alert signal is still at the active level). If the count value is over the final threshold (e.g., CATn_PW_min of FIG. 2) then a final type of alert may be determined and the controller 310 may issue a command to the memory 320. Once the type of alert is determined, the count value of the counter circuit 314 may be reset to an initial value (e.g., 0).

The memory 320 (e.g., 100 of FIG. 1) includes a number of alert sources 324. The alert sources 324 represent one or more components of the memory 320 which may generate faults which can be signaled to the controller 310 along the alert bus 302. In the example of FIG. 3, the alert sources 324 can identify 3 different types of fault and provides 3 different alert detection signals Alert1, Alert2 and Alert3. Responsive to receiving one of the alert detection signals, an alert generator circuit 322 drives the voltage on the alert pin 304 (and alert bus 302) to a voltage that represents an active alert signal. The alert generator circuit 322 includes a timing circuit 332 which determines an amount of time to keep the alert signal active based on the type of alert detection signal. For example, responsive to the first alert detection signal Alert1, the timing circuit 332 may count a first number of clock cycles (e.g., rising edges of CK) and the alert generator circuit 322 switches the alert signal back to an inactive level (e.g., drive the alert terminal 304 to a voltage which represents the inactive level) once the first number of clock cycles have been counted. The first number of clock cycles may be between the first and the second thresholds of the comparator circuit 316. Similarly, responsive to the second alert detection signal Alert2, the timing circuit 332 may keep the alert signal active for a second number of clock cycles, where the second number is between the third and the fourth thresholds. Responsive to the third alert detection signal Alert3, the alert generator circuit 322 may maintain the alert signal at the active level indefinitely, until the memory 320 receives a command from the controller 310.

In an example embodiment, the alert signals may be provided by an error correction circuit 326 (e.g., 120 of FIG. 1) and a refresh control circuit 326 (e.g., 116 of FIG. 1). The error correction circuit 326 may provide a first alert detection signal Alert1 when an error is detected which cannot be corrected. For example, the error correction circuit 326 may be capable of correcting up to one bit of error in the associated data bits. If there are more bits in error, the error correction circuit 326 may not be able to locate (and thus correct) those errors, and so the signal Alert1 is provided.

The refresh control circuit may provide two types of alert detection signal Alert2 and Alert3. The count values stored in the memory array (e.g., in counter memory cells 126 of FIG. 1) may be protected by an error correction or detection scheme (e.g., parity, redundant bits, etc.). If there is an error in one (or more) of the counts which cannot be corrected by that error correction or detection scheme, then the refresh control circuit 328 may provide the second type of alert detection signal Alert2. The refresh control circuit 328 includes an aggressor queue 329, which stores identified aggressor addresses (e.g., based on when an access count crosses a threshold). If the aggressor queue 329 becomes full, it may indicate that rows are becoming problematic faster than they are being addressed with targeted refresh operations. If the aggressor queue 329 fills up entirely, additional aggressor addresses may be missed. Accordingly, if the aggressor queue 329 becomes full (e.g., an address is loaded in a last open spot of the queue) then the refresh control circuit 329 may issue the signal Alert3.

The controller 310 may take various actions based on the type of alert detected by the alert logic circuit 312. Responsive to some types of alerts, the controller may take no action. Responsive to some types of alerts the controller 310 may pause access operations to the memory, may perform extra access operations, may issue a mode register read operation to determine more details, and/or may issue a command. For example, responsive to determining the first type of alert (e.g., a fault in the error correction circuit 326), the controller may perform its own error correction to fix the data and/or may write the data to the memory 320 again to restore it. Responsive to the second type of alert (a parity error in the count value) the controller 310 may take no action or slow down a rate at which access commands are issued. Responsive to the third type of alert (a full aggressor queue) the controller 310 may issue a refresh management command to the memory 320. Responsive to the refresh management command, the memory 320 may perform a targeted refresh operation.

In some embodiments, the memory 320 may include a mode register 330. Responsive to one or more of the alert detection signals Alert1-Alert3, the mode register 330 may store information about the alert. For example, the mode register 330 may store details about the detected fault, such as which row address is associated with the fault. In some situations, the controller 310 may perform a mode register read operation to retrieve the extra information about the fault.

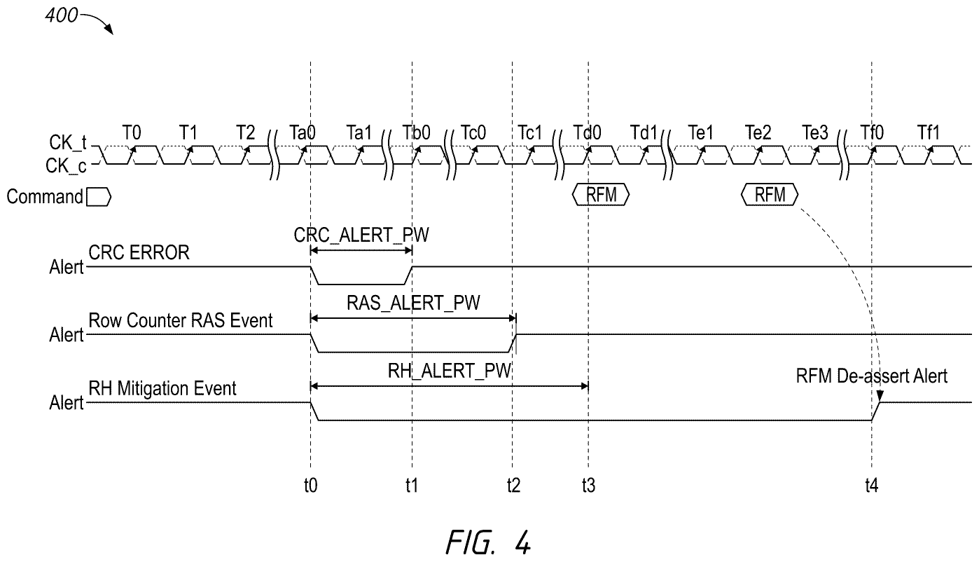

FIG. 4 is a timing chart of types of alert according to some embodiments of the present disclosure. The timing chart 400 of FIG. 4 may represent the operations of a memory device such as the ones shown in FIGS. 1 and 3. The timing chart may be an implementation of the alert signals shown in FIG. 2 in some example embodiments. The timing chart 400 shows an example embodiment with three types of alert are used, one which indicates a fault in the error correction circuit (a CRC error), one which represents an error correction fault in the counter memory cells (Row Counter RAS Event) and one which represents an aggressor queue becoming full (RH mitigation event).

The timing chart shows each of these three types of alert, aligned such that the alert signal becomes active at a same time t0. The traces of the different types of alert are shown aligned to allow comparison between their duration. Since the alert bus may be a single conductive element, each type of alert may be signaled one at a time (e.g., sequentially) rather than side-by-side as shown.

The timing chart 400 shows a clock signals CK_t and CK_c (e.g., CK and /CK of FIG. 1 or CK of FIG. 3) as well as signals along a command/address bus. Three different alerts are shown, each representing the voltage of an alert signal along an alert bus. All three alerts begin at a first time t0, when the alert signal becomes active (e.g., when the voltage on the alert pin and bus changes to an active level). At a second time t1, the alert signal returns to an inactive level to signal the first type of alert a CRC error. At the third time t2, which is after t1, the alert signal returns to an inactive level to signal the second type of alert, a row counter RAS event. At the fourth time t3, which is after t2, the alert signal remains active. Since the alert signal is still active, the controller issues a refresh management RFM command. At a fifth time t4, responsive to executing the RFM command the memory returns the alert signal to the inactive level.

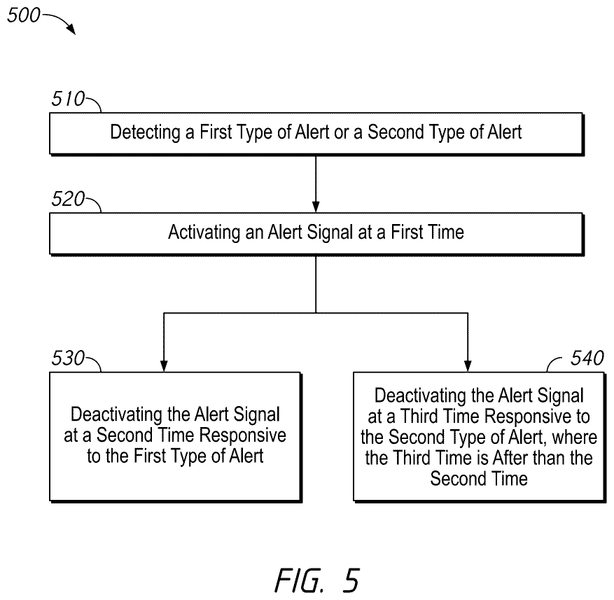

FIG. 5 is a flow chart of a method of providing multiple types of alert along an alert bus according to some embodiments of the present disclosure. The method 500 may, in some embodiments, be implemented by a memory device such as 100 of FIGS. 1 and/or 320 of FIG. 3. For example, the method 500 may represent a method of generating the alert signal patterns represented in FIGS. 2 and/or 4.

The method 500 may generally begin with box 510, which describes detecting a first type of alert or a second type of alert. For example, the method may include determining that a first type of error has occurred and providing a first alert detection signal or determining that a second type of error has occurred and providing a second alert detection signal.

Box 510 is followed by box 520, which describes activating an alert signal at a first time responsive to detecting the first or the second type of alert. The method 500 may include activating the alert signal by driving a voltage along an alert terminal (or alert pin) and alert bus to an active level. For example, an alert generator circuit (e.g., 140 of FIGS. 1 and/or 322 of FIG. 3) may receive the first or the second alert detection signal and begin providing the alert signal at the active level responsive to the first or the second type of alert detection signal.

Box 520 is followed by either box 530 or box 540 depending on the type of alert. Box 530 describes deactivating the alert signal at a second time responsive to the first type of alert. Box 540 describes deactivating the alert signal at a third time responsive to the second type of alert, where the third time is longer than the second time. The method 500 may include activating the alert signal for a first pulse width responsive to the first type of alert and activating the alert signal for a second pulse width responsive to the second type of alert.

In some embodiments, the method 500 may include detecting a third type of alert, activating the alert signal at the first time responsive to the third type of alert and maintaining the alert signal at the active level until a command is received from a controller. For example, the method 500 may include determining that an address is an aggressor address and adding it to an aggressor queue (e.g., 329 of FIG. 3), detecting the third type of alert based on the aggressor queue becoming full, receiving a refresh management command, deactivating the alert signal responsive to the refresh management command, and performing a targeted refresh operation responsive to the refresh management command.

The method 500 may include receiving a clock signal (e.g., CK) from a controller and counting a number of cycles of the clock signal beginning at the first time. The method 500 may include deactivating the alert signal when the number of clock cycles reaches a first value when the first type of alert was detected and deactivating the alert signal when the number of clock cycles reaches a second value when the second type of alert was detected.

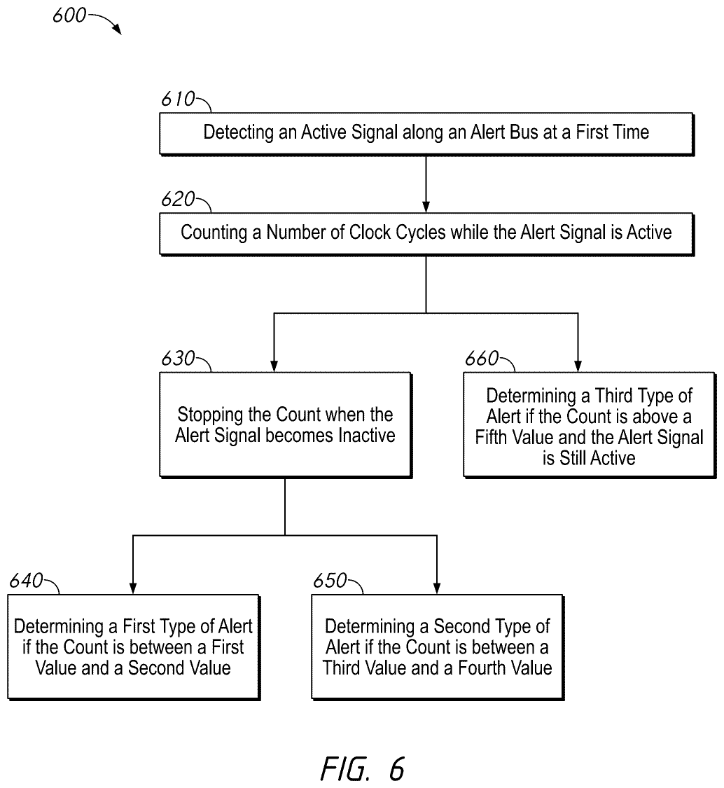

FIG. 6 is a flow chart of a method of determining a type of alert along an alert bus with a controller according to some embodiments of the present disclosure. The method 600 may, in some embodiments, be implemented by the controller 150 of FIGS. 1 and/or 310 of FIG. 3. The method 600 may represent a method of determining different types of alerts based on a pulse width of the alert signal, as described in the examples of FIGS. 2 and 4. In some embodiments, the method 600 may describe receiving the signals generated by the method of FIG. 5.

The method 600 may generally begin with box 610, which describes detecting an active signal along an alert bus at a first time. The alert bus (e.g., 302 of FIG. 3) may be coupled to an alert terminal or alert pin of the memory. The method 600 may include determining that a voltage along the alert bus has crossed a threshold. For example, if the alert signal is inactive at a first voltage and active at a second voltage below the first voltage, the method may include determining that the voltage has fallen below a threshold value.

Box 610 may be followed by box 620, which describes counting a number of clock cycles while the signal is active. The method 600 may include beginning to count the number of clock cycles responsive to detecting that the alert signal has become active. The counting may include changing a count value (e.g., by incrementing it) responsive to each cycle of the clock signal (e.g., each rising edge of the clock signal) for example with the counter circuit 314 of FIG. 3. The method 600 may include comparing the count value to a threshold (e.g., with comparator circuit 316 of FIG. 3) to determine if the method should proceed to block 630 or to block 660. Block 620 may be followed by block 630 if the count of clock cycles is below the threshold when the alert signal becomes inactive. Block 620 may be followed by block 660 if the count value crosses the threshold.

Block 630 describes stopping the count when the alert signal becomes inactive. For example, the method 600 may include determining that a voltage on the alert bus has crossed to an inactive level. In some embodiments, the method may include determining that the voltage is above a threshold voltage. When the count value is stopped, the method 600 may include comparing the stopped count value to a number of threshold values. The method 600 may include determining a type of alert based on the comparison of the stopped count value to the threshold values. FIG. 6 shows two different example types of alert.

Block 630 may be followed by block 640 or by block 650 depending on the count value. Block 640 describes determining a first type of alert if the count is between a first value and a second value. Block 650 describes determining a second type of alert if the count is between a third value and a fourth value. The second value (e.g., CAT1_PW_max of FIG. 2) may be greater than the first value (e.g., CAT1_PW_min of FIG. 2), the third value (e.g., CAT2_PW_min of FIG. 2) may be greater than the second value, and the fourth value (e.g., CAT2_PW_max of FIG. 2) may be greater than the third value.

If the count of clock cycles crosses a threshold while the alert signal is still active, then block 620 may be followed by block 660, which describes determining a third type of alert if the count is above a fifth value (e.g., a threshold such as CATn_PW_min of FIG. 2) and the alert signal is still active. The method 600 may include providing a command to the memory responsive to determining the third type of alert. The method 600 may include returning the alert signal to an inactive level responsive to the command.

The method 600 may include taking one or more actions based on the type of alert which was determined. In some embodiments, the method 600 may include performing a mode register read operation on a mode register of the memory to retrieve additional information based on the type of alert.

It is to be appreciated that any one of the examples, embodiments or processes described herein may be combined with one or more other examples, embodiments and/or processes or be separated and/or performed amongst separate devices or device portions in accordance with the present systems, devices and methods.

Finally, the above discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
an alert terminal;
at least one alert source circuit configured to provide a first alert detection signal responsive to a first type of alert or a second alert detection signal responsive to a second type of alert; and
an alert generator circuit configured to provide an alert signal to the alert terminal at an active level for a first duration responsive to the first alert detection signal or to provide the alert signal to the alert terminal at the active level for a second duration responsive to the second alert detection signal.

2. The apparatus of claim 1, wherein the at least one alert source circuit is further configured to provide a third alert detection signal, and wherein responsive to the third alert detection signal, the alert generator circuit is further configured to provide the alert signal to the alert terminal at the active level until a command is received.

3. The apparatus of claim 1 further comprising:
a clock terminal configured to receive a clock signal,
wherein the alert generator circuit comprises a timing circuit configured to determine the first duration and the second duration based, in part, on a number of cycles of the clock signal.

4. The apparatus of claim 1, further comprising a mode register, wherein responsive to the first alert detection signal the mode register is configured to store information about the first type of alert.

5. The apparatus of claim 1, further comprising:
a memory array configured to store data bits and associated parity bits; and
an error correction circuit configured to correct the data bits based on the associated parity bits and provide the first alert detection signal responsive to determining that the data bits include an error which cannot be corrected by the error correction circuit.

6. The apparatus of claim 1, further comprising:
a memory array comprising a plurality of word lines, each of which is associated with a respective row address and count value; and
refresh control circuit configured to determine that one of the plurality of word lines is an aggressor row based on the respective count value and store the respective row address in an aggressor queue, wherein the refresh control circuit is configured to provide the second alert detection signal responsive to detecting an error with the respective count value and configured to provide a third alert detection signal responsive to the aggressor queue being full.

7. The apparatus of claim 1, wherein the alert terminal is coupled via an alert bus to a controller.

8. A system comprising:
an alert bus;
a memory configured to provide an alert signal along the alert bus at an active level for a period of time; and
a controller configured to determine a duration of the period of time and determine a type of alert based on the duration of the alert signal.

9. The system of claim 8, further comprising a clock bus,
wherein the controller further comprises a clock generator circuit configured to provide a clock signal along the clock bus, and
wherein the memory is configured to provide the alert signal at the active level for a number of cycles of the clock signal wherein the number is based on the type of alert.

10. The system of claim 9, wherein the controller includes an alert logic circuit configured to count a number of the cycles of the clock signal starting when the alert signal changes to the active level and ending when the alert signal changes to an inactive level.

11. The system of claim 8, wherein the controller includes an alert logic circuit configured to determine a first type of alert if the period of time is between a first value and a second value, determine a second type of alert if the period of time is between a third value and a fourth value, wherein the second value is longer than the first value, the third value is longer than the second value, and the fourth value is longer than the third value.

12. The system of claim 11, wherein the alert logic circuit is further configured to determine a third type of alert if the alert signal remains at the active level for longer than a fifth value, wherein the fifth value is longer than the fourth value.

13. The system of claim 12, wherein responsive to the determination of the third type of alert the controller is configured to provide a command to the memory and wherein responsive to the command the memory is configured to provide the alert signal at an inactive level.

14. The system of claim 8, wherein the memory includes a mode register, and wherein the controller configured to perform a mode register read operation on the mode register responsive to a first type of alert signal.

15. A method comprising:
detecting a first type of alert or a second type of alert;
activating an alert signal at a first time responsive to the first type or the second type of alert;
deactivating the alert signal at a second time responsive to the first type of alert; and
deactivating the alert signal at a third time responsive to the second type of alert, wherein the third time is after the second time.

16. The method of claim 15, further comprising:
detecting a third type of alert;
activating the alert signal at the first time responsive to the third type of alert; and
maintaining the alert signal at the active level until a command is received from a controller.

17. The method of claim 16, further comprising:
determining that an address is an aggressor address and adding it to an aggressor queue;
detecting the third type of alert based on the aggressor queue becoming full;
receiving a refresh management command;
deactivating the alert signal responsive to the refresh management command; and
performing a targeted refresh operation responsive to the refresh management command.

18. The method of claim 15, further comprising:
receiving a clock signal;
counting a number of clock cycles beginning at the first time;
deactivating the alert signal when the number of clock cycles reaches a first value responsive to the first type of alert; and
deactivating the alert signal when the number of clock cycles reaches a second value responsive to the second type of alert.

19. The method of claim 15, further comprising:
detecting the alert signal at the active level;
counting a time that the alert signal is at the active level; and
determining the type of alert based on the time.

20. The method of claim 19, further comprising:
providing a command responsive to determining that the count is above a threshold and the alert signal is still at the active level.
